(19) United States
(12) Patent Application Publication
(10) Pub. No.: US 2022/0098717 A1
(43) Pub. Date: Mar. 31, 2022

(54) FILM FORMING APPARATUS AND FILM FORMING METHOD

(71) Applicant: TOKYO ELECTRON LIMITED, Tokyo (JP)

(72) Inventors: Kenichi IMAKITA, Yamanashi (JP); Kazunaga ONO, Yamanashi (JP); Toru KITADA, Yamanashi (JP); Keisuke SATO, Hillsboro, OR (US); Atsushi GOMI, Yamanashi (JP); Hiroyuki YOKOHARA, Yamanashi (JP); Hiroshi SONE, Tokyo (JP)

(21) Appl. No.: 17/428,597

(22) PCT Filed: Sep. 20, 2019
(86) PCT No.: PCT/JP2019/036980

§ 371 Date: Aug. 4, 2021

(30) Foreign Application Priority Data
Feb. 8, 2019 (JP) 2019-021298

(51) Int. Cl. C23C 14/00; C23C 14/50; C23C 14/08; C23C 14/56; C23C 14/34

(52) U.S. Cl. CPC C23C 14/0068; C23C 14/505; C23C 14/34; C23C 14/56; C23C 14/08

(57) ABSTRACT

A film forming apparatus according to the present invention comprises: a processing chamber; a substrate holder for holding a substrate within the processing chamber; a target electrode, disposed above the substrate holder, for holding a metal target and supplying electrical power from a power source to the target; an oxidizing gas introduction mechanism for supplying an oxidizing gas to the substrate; and a gas supply unit for supplying an inert gas to the space where the target is disposed. Constituent metal is discharged from the target in the form of sputter particles, whereby a metal film is deposited on the substrate, and the metal film is oxidized by the oxidizing gas introduced by the oxidizing gas introduction mechanism, thereby forming a metal oxide film. When the oxidizing gas is introduced, the gas supply unit supplies the inert gas to the space where the target is disposed so that the pressure therein is positive with respect to the pressure in a processing space.

### TECHNICAL FIELD

The present disclosure relates to a film forming apparatus and a film forming method.

### BACKGROUND

A magnetoresistive element including a magnetic film and a metal oxide film is used for a magnetic device such as a magnetoresistive random access memory (MRAM), a hard disk drive (HDD), or the like. As a film forming apparatus for forming a metal oxide film, Patent Document 1 discloses an apparatus including a processing chamber, a holding part for holding a target object in the processing chamber, a metal target, and an introduction mechanism for supplying oxygen gas toward the holding part. In the film forming apparatus of Patent Document 1, after a metal film is deposited on the target object by sputtering the target, the oxygen gas is introduced to oxidize and crystallize the metal film. In this manner, since the deposition of the metal film and the oxidation and crystallization of the metal film are performed in one processing chamber, the metal oxide film can be formed quickly.

Patent Document 1: Japanese Patent Application Publication No. 2016-33244

### SUMMARY

The present disclosure provides a film forming apparatus and a film forming method capable of suppressing oxidation of a metal target in the case of performing deposition of a metal film and oxidation of the deposited metal film in the same processing chamber.

In accordance with an aspect of the present disclosure, there is provided a film forming apparatus for forming a metal oxide film on a substrate, comprising: a processing chamber; a substrate holder configured to hold a substrate in the processing chamber; a target electrode disposed above the substrate holder and configured to hold a target made of a metal and supply an electrical power from a power source to the target; an oxidizing gas introduction mechanism configured to supply an oxidizing gas to the substrate held by the substrate holder; and a gas supply unit configured to supply an inert gas to a target arrangement space where the target is disposed, wherein a constituent metal is discharged in the form of sputter particles from the target supplied with the electrical power through the target electrode, and deposited on the substrate as a metal film, and the metal film is oxidized by the oxidizing gas introduced by the oxidizing gas introduction mechanism, thereby forming a metal oxide film, and when the oxidizing gas is introduced, the gas supply unit supplies the inert gas to the target arrangement space so that a pressure in the target arrangement space is positive with respect to a pressure in a processing space where the substrate is disposed.

### Effect of the Invention

The present disclosure provides a film forming apparatus and a film forming method capable of suppressing oxidation of a metal target in the case of performing deposition of a metal film and oxidation of the deposited metal film in the same processing chamber.

### BRIEF DESCRIPTION OF THE DRAWINGS

FIG. 1 is a cross-sectional view showing a film forming apparatus according to a first embodiment.

FIG. 2 is a flowchart showing a film forming method according to one embodiment that can be performed by the film forming apparatus according to the first embodiment.

FIG. 3 is a cross-sectional view showing a state at the time of depositing a metal film in the film forming apparatus according to the first embodiment.

FIG. 4 is a cross-sectional view showing a state in which sputter particles are emitted from a target in the film forming apparatus according to the first embodiment in the state of FIG. 5.

FIG. 5 is a cross-sectional view for explaining flow of an oxidizing gas in the case where no inert gas is supplied during the supply of the oxidizing gas.

FIG. 6 is a cross-sectional view for explaining a state in which an inert gas is supplied during the supply of the oxidizing gas.

FIG. 7 shows a test result that has confirmed an effect of preventing intrusion of O₂ gas by supplying Ar gas as an inert gas during oxidation treatment in the first embodiment.

FIG. 8 shows a test result that has confirmed an effect obtained by supplying Ar gas together with O₂ gas during the oxidation treatment in the first embodiment.

FIG. 9 is a cross-sectional view showing a part of a film forming apparatus according to a second embodiment.

FIG. 10 shows a state in which a partition unit (first partition plate) is raised up in the film forming apparatus of FIG. 9.

FIG. 11 is a flowchart showing a film forming method according to one embodiment that can be performed by the film forming apparatus according to the second embodiment.

FIG. 12 is a flowchart showing a film forming method according to another embodiment that can be performed by the film forming apparatus according to the second embodiment.

FIG. 13 is a cross-sectional view for explaining features of the film forming method of FIG. 12.

FIG. 14 is a flowchart showing a film forming method according to still another embodiment that can be performed by the film forming apparatus according to the second embodiment.

FIG. 15 is a cross-sectional view showing a modification of the film forming apparatus according to the second embodiment.

### DETAILED DESCRIPTION

Hereinafter, embodiments will be described in detail with reference to the accompanying drawings.

### First Embodiment

First, a first embodiment will be described.

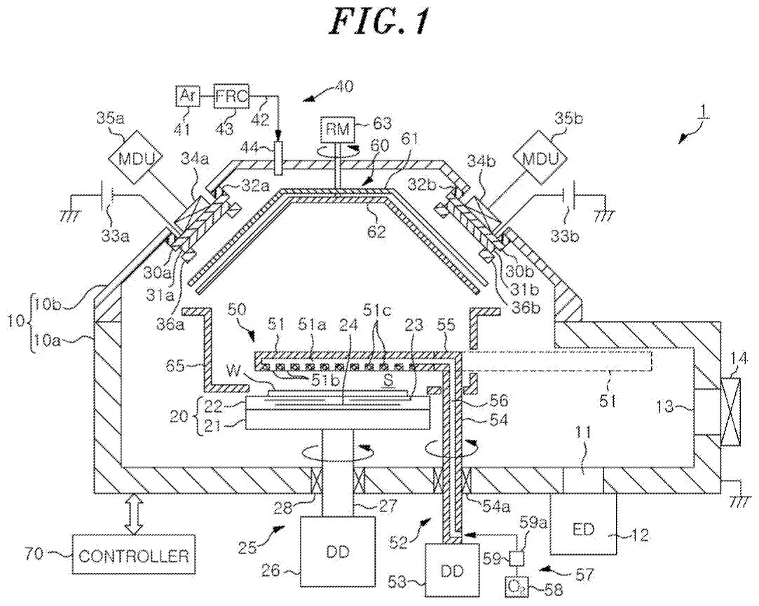

FIG. 1 is a cross-sectional view showing a film forming apparatus according to the first embodiment. A film forming apparatus 1 of the present embodiment deposits a metal film on a substrate W by sputtering, and then performs oxidation treatment to form a metal oxide film. The substrate W may be, e.g., a wafer made of AlTiC, Si, glass, or the like, but is not limited thereto.

The film forming apparatus 1 includes a processing chamber 10, a substrate holder 20, target electrodes 30a and 30b, a gas supply part 40, an oxidizing gas introduction mechanism 50, a partition unit 60, and a controller 70.

The processing chamber 10 is made of, e.g., aluminum, and defines a processing chamber for processing the substrate W. The processing chamber 10 is connected to a ground potential. The processing chamber 10 includes a chamber main body 10a having an upper opening, and a lid 10b for closing the upper opening of the chamber main body 10a. The lid 10b has a truncated cone shape.

An exhaust port 11 is formed at a bottom portion of the processing chamber 10, and an exhaust device (ED) 12 is connected to the exhaust port 11. The exhaust device 12 includes a pressure control valve and a vacuum pump, and the inside of the processing chamber 10 is vacuum exhausted to a predetermined vacuum level by the exhaust device 12.

A loading/unloading port 13 for loading/unloading the substrate W into/from an adjacent transfer chamber (not shown) is formed on a sidewall of the processing chamber 10. The loading/unloading port 13 is opened and closed by a gate valve 14.

The substrate holder 20 has a substantially disc shape and is disposed near the bottom portion in the processing chamber 10 to hold the substrate W horizontally. In the present embodiment, the substrate holder 20 includes a base portion 21 and an electrostatic chuck 22. The base portion 21 is made of, e.g., aluminum. The electrostatic chuck 22 is made of a dielectric material and has an electrode 23 therein. The substrate W is electrostatically attracted to the surface of the electrostatic chuck 22 by an electrostatic force generated by applying a DC voltage from a DC power source (not shown) to the electrode 23. In the illustrated example, the electrostatic chuck 22 is a bipolar electrostatic chuck. However, the electrostatic chuck 22 may be a unipolar electrostatic chuck.

Further, a heater 24 is disposed in the substrate holder 20. The heater 24 has, e.g., a heating resistance element, and emits heat by an electrical power supplied from a heater power source (not shown) to heat the substrate W. The heater 24 is used as a first heater for oxidizing the metal film deposited on the surface of the substrate W. When the metal is Mg, the heater 24 heats the substrate W to a temperature within a range of 50° C. to 300° C. In FIG. 1, the heater 24 is disposed in the electrostatic chuck 22. However, the heater 24 may be disposed in the base portion 21.

The substrate holder 20 is connected to a driving unit 25. The driving unit 25 has a driving device (DD) 26 and a support shaft 27. The driving device 26 is disposed below the processing chamber 10. The support shaft 27 extends from the driving device 26 penetrating through the bottom wall of the processing chamber 10, and the tip end thereof is connected to the center of the bottom surface of the substrate holder 20. The driving device 26 rotates and vertically moves up and down the substrate holder 20 via the support shaft 27. The space between the support shaft 27 and the bottom wall of the processing chamber 10 is sealed by a sealing member 28. By providing the sealing member 28, the support shaft 27 can rotate and vertically move while maintaining the vacuum state of the processing chamber 10. The sealing member 28 may be, e.g., a magnetic fluid seal.

The target electrodes 30a and 30b are respectively electrically connected to targets 31a and 31b disposed above the substrate holder 20 and hold the targets 31a and 31b. The target electrodes 30a and 30b are respectively attached on inclined surfaces of the lid 10b of the processing chamber 10 via insulating members 32a and 32b, obliquely with respect to the substrate W. The targets 31a and 31b are made of a metal forming a metal film to be deposited, and the material thereof is appropriately selected depending on the type of a metal oxide film to be formed. For example, the targets 31a and 31b are made of Mg, Al, or the like. Although the number of the targets is two in this example, the number of the targets is not limited thereto and may be one or more, e.g., four.

Power sources 33a and 33b are connected to the target electrodes 30a and 30b, respectively. In this example, the power sources 33a and 33b are DC power sources. However, the power sources 33a and 33b may be AC power sources. The power from the power sources 33a and 33b is supplied to the targets 31a and 31b through the target electrodes 30a and 30b, respectively. Cathode magnets 34a and 34b are disposed on the sides of the target electrodes 30a and 30b opposite to the sides where the targets 31a and 31b are disposed, respectively. Magnet driving units (MDU) 35a and 35b are connected to the cathode magnets 34a and 34b, respectively. Ring-shaped members 36a and 36b for restricting the emission direction of sputter particles are disposed at outer peripheral portions of the surfaces of the targets 31a and 31b, respectively. The ring-shaped members 36a and 36b are grounded.

In the present embodiment, the gas supply unit 40 includes a gas supply source 41, a gas supply line 42 extending from the gas supply source 41, a flow rate controller (FRC) 43, such as a mass flow controller, disposed in the gas supply pipe 42, and a gas introducing member 44. An inert gas, e.g., a noble gas such as Ar, He, Ne, Kr, He, or the like is supplied as a gas to be excited in the processing chamber 10 from the gas supply source 41 into the processing chamber 10 through the gas supply line 42 and the gas introducing member 44.

The gas supply unit 40 is used as a sputtering gas supply mechanism, and also functions an oxygen gas arrival suppression mechanism for suppressing an oxidizing gas to be described later from reaching the targets 31a and 31b.

When the gas supply unit 40 functions as the sputtering gas supply mechanism, the gas from the gas supply unit 40 is supplied as a sputtering gas into the processing chamber 10 when a metal film is deposited by sputtering. The supplied gas is excited by applying a voltage from the power sources 33a and 33b to the targets 31a and 31b through the target electrodes 30a and 30b, respectively, thereby generating plasma. On the other hand, when the cathode magnets 34a and 34b are driven by the magnet driving units 35a and 35b, respectively, a magnetic field is generated around the targets 31a and 31b, so that the plasma is concentrated near the targets 31a and 31b. Then, positive ions in the plasma collide with the targets 31a and 31b, so that the constituent metals are released as sputter particles from the targets 31a and 31b and deposited on the substrate W.

A voltage may be applied from both of the power sources 33a and 33b so that sputter particles can be emitted from both the targets 31a and 31b, or may be applied to only one of the targets 31a and 31b so that sputter particles can be emitted.

The case where the gas supply unit 40 functions as the oxidizing gas arrival suppression mechanism will be described later in detail.

The oxidizing gas introduction mechanism 50 includes a head portion 51, a moving mechanism 52, and an oxidizing gas supply unit 57. The head portion 51 has a substantially disc shape. The moving mechanism 52 has a driving device (DD) 53 and a support shaft 54. The driving device 53 is disposed below the processing chamber 10. The support shaft 54 extends from the driving device 53 penetrating through the bottom wall of the processing chamber 10, and the tip end thereof is connected to the bottom portion of a connection portion 55. The connection portion 55 is coupled to the head portion 51.

The space between the support shaft 54 and the bottom wall of the processing chamber 10 is sealed by a sealing member 54a. The sealing member 54a may be, e.g., a magnetic fluid seal. When the driving device 53 rotates the support shaft 54, the head portion 51 can be moved between an oxidation treatment position in a processing space S directly above the substrate holder 20 and a retreat position distant from the processing space S indicated by dashed lines in the drawing.

A circular gas diffusion space 51a and a plurality of gas injection holes 51b that extend downward from the gas diffusion space 51a and are opened are formed in the head portion 51. A gas line 56 is formed in the support shaft 54 and the connection portion 55, and one end of the gas line 56 is connected to the gas diffusion space 51a. The other end of the gas line 56 is disposed below the processing chamber 10 and connected to the oxidizing gas supply unit 57. The oxidizing gas supply unit 57 includes a gas supply source 58, a gas supply line 59 extending from the gas supply source 58 and connected to the gas line 56, and a flow rate controller (FRC) 59a such as a mass flow controller, disposed in the gas supply line 9. The oxidizing gas, e.g., an oxygen gas (O₂ gas), is supplied from the gas supply source 58. When the substrate holder 20 is located at the oxidation treatment position, the oxidizing gas is supplied to the substrate W held by the substrate holder 20 through the gas supply line 59, the gas line 56, the gas diffusion space 51a, and the gas injection holes 51b.

The head portion 51 is provided with a heater 51c. Various heating methods such as resistance heating, lamp heating, induction heating, and microwave heating are applicable for the heater 51c. The heater 51c emits heat by an electrical power supplied from a heater power source (not shown). The heater 51c is used as a second heater for crystallizing the metal oxide film formed on the substrate. When the metal is Mg, the heater 51c heats the substrate W to a temperature within a range of 250° C. to 400° C. The heater 51c may also be used to heat the oxidizing gas in the case of supplying the oxidizing gas (e.g., O₂ gas) from the head portion 51. Accordingly, it is possible to further reduce the time required for the metal oxidation.

The partition unit 60 functions as a shielding member for shielding the targets 31a and 31b, and partitions the space in which the targets 31a and 31b are arranged (target arrangement space) and the processing space S in which the substrate is disposed. The partition unit 60 has a first partition plate 61 and a second partition plate 62 disposed below the first partition plate 61. Both of the first partition plate 61 and the second partition plate 62 have a truncated cone shape corresponding to the shape of the lid portion 10b of the processing chamber 10 and overlap with each other in a vertical direction. The first partition plate 61 and the second partition plate 62 have openings having sizes corresponding to those of the targets 31a and 31b, respectively. Further, the first partition plate 61 and the second partition plate 62 can be rotated independently by the rotation mechanism (RM) 63. The first partition plate 61 and the second partition plate 62 can be rotated to an open state in which the openings are located at positions corresponding to the targets 31a and 31b and to a closed state (partition state) in which the openings are located at positions that do not correspond to the targets 31a and 31b. When the first partition plate 61 and the second partition plate 62 are in the open state, the centers of the targets 31a and 31b coincide with the centers of the openings. When the first partition plate 61 and the second partition plate 62 are in the open state, the shielding by the partition unit 60 is released and a metal film can be deposited by sputtering. On the other hand, when the first partition plate 61 and the second partition plate 62 are in the closed state, the target arrangement space and the processing space S are partitioned.

The second partition plate 62 is closed when the targets 31a and 31b are sputter-cleaned by opening the first partition plate 61, and is shielded so that the sputter particles are not emitted to the processing space during the sputter-cleaning of the target targets 31a and 31b.

A shielding member 65 is disposed above the substrate holder 20 to extend from the outer end of the upper surface of the substrate holder 20 to the vicinity of the lower end of the partition unit 60. The shielding member 65 has a function of suppressing the oxidizing gas supplied from the oxidizing gas introduction mechanism 50 from being diffused toward the targets 31a and 31b.

The controller 70 is comprised of a computer and includes a main controller having a CPU for controlling individual components of the film forming apparatus 1, such as the power sources 33a and 33b, the exhaust device 12, the driving unit 25, the gas supply unit 40, the oxidizing gas introduction mechanism 50, the partition unit 60, and the like. The controller 70 further includes an input device such as a keyboard or a mouse, an output device, a display device, and a storage device. The main controller of the controller sets a storage medium in which a processing recipe is stored in the storage device, and causes the film forming apparatus 1 to perform a predetermined operation based on the processing recipe called from the storage medium.

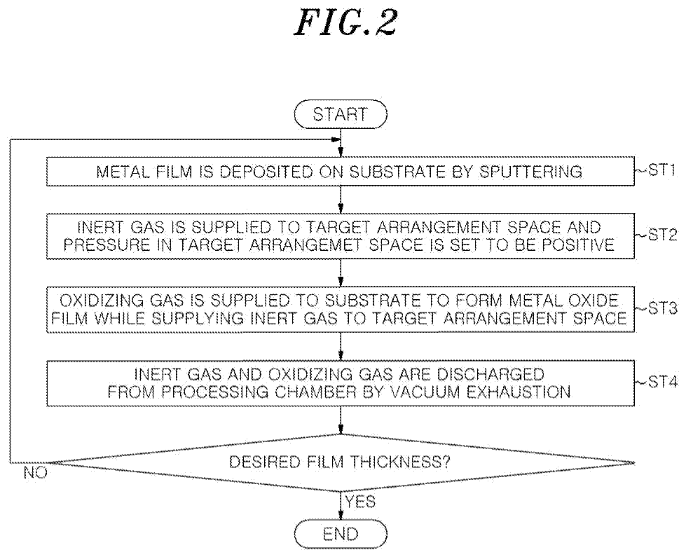

Next, a film forming method of one embodiment that can be performed by the film forming apparatus according to the first embodiment configured as described above will be described with reference to the flowchart of FIG. 2.

The film forming method of FIG. 2 includes steps ST1, ST2, ST3, and ST4.

First, prior to the execution of the film forming method, the gate valve 14 is opened, and the substrate W is loaded into the processing chamber 10 from the transfer chamber (not shown) adjacent to the processing chamber 10 by a transfer unit (not shown) and held by the substrate holder 20.

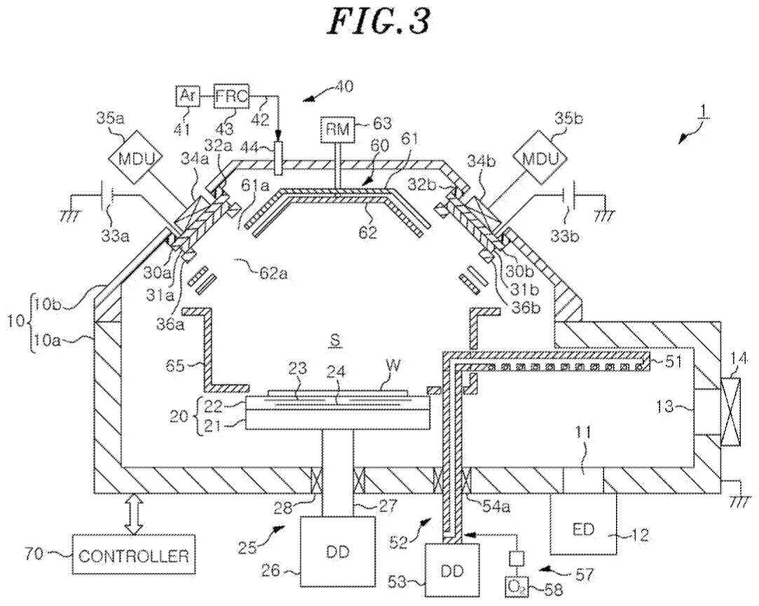

In step ST1, a metal film such as an Mg film, an Al film, or the like is deposited on the substrate W on the substrate holder 20 by sputtering. At this time, prior to the deposition of the metal film, the partition unit 60 is set to the open state in the film forming apparatus 1 as shown in FIG. 3. Specifically, the first partition plate 61 and the second partition plate 62 are set to the open state such that the openings 61a and 62a are located at positions corresponding to the targets 31a and 31b, respectively (the centers of the openings 61a and 62a coincide with the centers of the targets 31a and 31b, respectively). Further, the head portion 51 of the oxidizing gas introduction mechanism 50 is located at the retreat position.

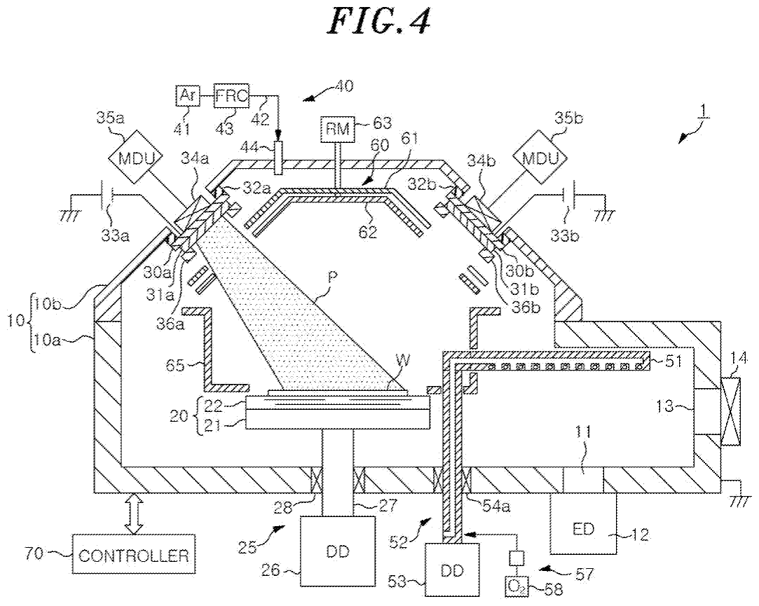

Specifically, the sputtering of step ST1 is performed as follows. First, an inert gas such as Ar gas is introduced into the processing chamber 10 from the gas supply unit 40 while adjusting a pressure in the processing chamber 10 to a predetermined pressure by the exhaust device 12. Next, plasma is generated by applying an electrical power from the power sources 33a and 33b to the targets 31a and 31b through the target electrodes 30a and 30b, respectively, and a magnetic field from the cathode magnets 34a and 34b is made to act. At this time, the cathode magnets 34a and 34b are driven by the magnet driving units 35a and 35b, respectively. Accordingly, the positive ions in the plasma collide with the targets 31a and 31b, and sputter particles P made of the constituent metals of the targets 31a and 31b are emitted from the targets 31a and 31b as shown in FIG. 4. A metal film is deposited on the substrate W by the emitted sputter particles P. At this time, as described above, the sputter particles may be emitted from both of the targets 31a and 31b, or may be emitted from only one of the targets 31a and 31b. FIG. 4 shows a state in which the sputter particles P are emitted from the target 31a. The pressure in step ST1 is preferably within a range of 1×10⁻⁵ Torr to 1×10⁻² Torr (1.3×10⁻³Pa to 1.3 Pa).

In step ST2, an inert gas such as Ar, He, Ne, Kr, He or the like is supplied from the gas supply unit 40 to the target arrangement space in which the targets 31a and 31b are arranged, and a pressure in the target arrangement space is set to be positive compared to a pressure in the processing space S near the substrate W. At this time, the first partition plate 61 and the second partition plate 61 are rotated to set the partition unit 60 in the closed state.

In step ST3, an oxidizing gas, e.g., O₂ gas, is supplied to the substrate W held by the substrate holder 20 while supplying an inert gas to the target arrangement space, and the metal film deposited on the substrate W is oxidized to form a metal oxide film. At this time, the head portion 51 of the oxidizing gas introduction mechanism 50 is moved to the oxidation treatment position directly above the substrate holder 20, and the oxidizing gas is supplied from the head portion 51 of the oxidizing gas introduction mechanism 50 to the substrate W. Further, the substrate W is heated by the heater 24 to a temperature of, e.g., 50° C. to 300° C. In step ST3, after the oxide film is formed, the substrate W may be heated to a temperature of, e.g., 250° C. to 400° C., by the heater 51c to crystallize the metal oxide film. The pressure in step ST3 is preferably within a range of 1×10⁻⁷ Torr to 2×10⁻² Torr (1.3×10⁻⁵ Pa to 2.6 Pa).

In step ST4, the inert gas supplied in step ST2 and the oxidizing gas supplied in step ST3 are discharged from the processing chamber 10 by vacuum exhaustion.

By repeating steps ST1 to ST4 a predetermined number of times, a metal oxide film having a desired film thickness is formed.

If necessary, prior to the deposition of the metal film in step ST1, a voltage may be applied to the targets 31a and 31b to sputter-clean the targets 31a and 31b in a state the first partition plate 61 is set to the open state the second partition plate 62 is set to the closed state. In this way, natural oxide films on the surfaces of the targets 31a and 31b are removed. At this time, the sputter particles are deposited on the second partition plate 62. After the completion of the sputter cleaning, the partition plate 62 is set to the open state. Accordingly, the partition unit 60 is set to the open state, and the deposition of the metal film in step ST1 is performed.

In accordance with the present embodiment, since the deposition of the metal film and the oxidation treatment of the metal film can be performed in one processing chamber, the film formation of the metal oxide film can be performed quickly as in the technique of Patent Document 1.

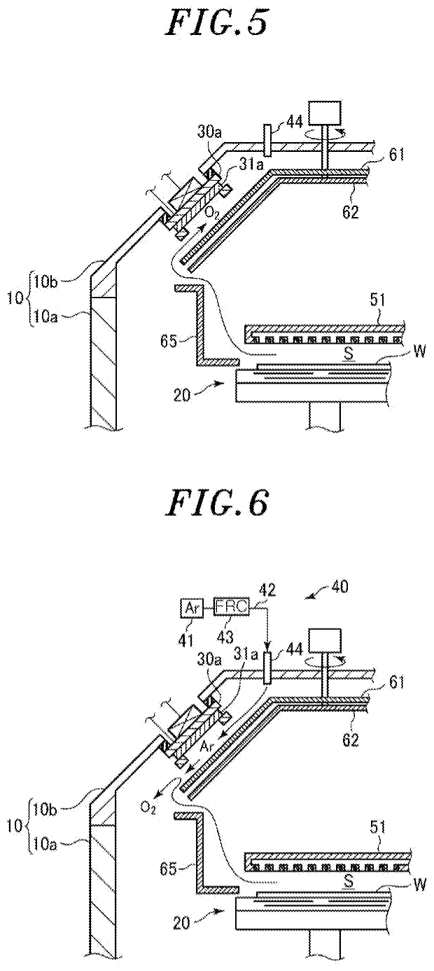

However, in the technique of Patent Document 1, since the oxidation treatment is performed in the same processing chamber, the oxidizing gas (O₂ gas) reaches the targets 31a and 31b during the oxidation treatment, and the surfaces of the targets 31a and 31b are naturally oxidized as shown in FIG. 5. Particularly, local oxidation is likely to occur at the peripheral portion.

When the natural oxide films are formed on the surfaces of the targets 31a and 31b, the sputtering rate decreases. In addition, a discharge voltage changes due to the surface oxidation, and arc discharge occurs between the natural oxide films and the surfaces of the targets 31a and 31b or between the natural oxide films and the inner wall of the processing chamber. Also, the thickness of the metal film changes. Accordingly, in the case of forming the metal oxide film on multiple substrates W, the thickness of the metal oxide film is reduced and it is difficult to stably manufacture an element having the same characteristics.

Conventionally, it is known that when a sputtering target contains impurities, the impurities are locally charged and, thus, arc occurs. Also in the present embodiment, it is considered that micro-arc occurs because an oxide portion is locally charged. In this case, it is known that by applying the voltage of a temporarily inverted pulse shape to the target (cathode), electrons are exposed on the target surface to remove the accumulated charges and the occurrence of arc is suppressed.

However, even if the occurrence of arc can be suppressed by the above method, that is not a fundamental solution because the natural oxidation of the target surface is not prevented.

Therefore, in the present embodiment, after the metal film is deposited, an inert gas is supplied from the gas supply unit 40 to the target arrangement space, and the pressure in the target arrangement space is set to be positive with respect to the pressure in the processing space S near the substrate W. Then, the oxidation treatment is performed. Accordingly, as shown in FIG. 6, the oxidizing gas (O₂ gas) is suppressed from reaching the targets 31a and 31b.

Therefore, it is possible to suppress the oxidation of the surfaces of the targets 31a and 31b, and it is possible to suppress a decrease in the sputtering rate, a change in the discharge voltage, and the occurrence of arc discharge at the time of depositing the metal film by sputtering. In addition, the change in the thickness of the metal film is suppressed. Accordingly, it is possible to stably manufacture an element having the same characteristics.

Next, a test example related to the first embodiment will be described.

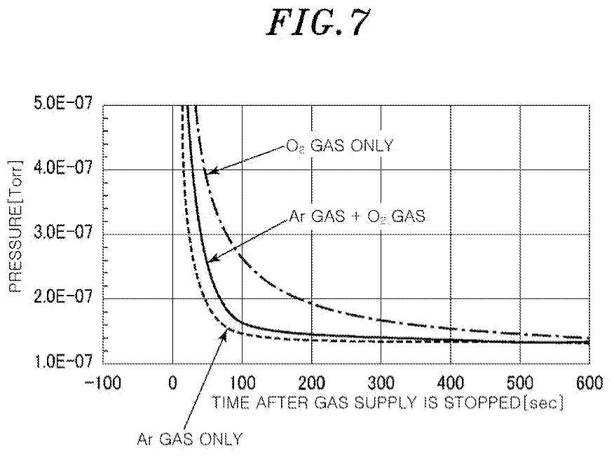

First, the effect of preventing the intrusion of O₂ gas by supplying Ar gas as an inert gas during the oxidation treatment was checked. Here, the pressure change after the gas supply was monitored in the case of supplying only O₂ gas at 1000 sccm, in the case of supplying each of O₂ gas and Ar gas at 1000 sccm, and in the case of supplying only Ar gas at 1000 sccm. The result is shown in FIG. 7.

As shown in FIG. 7, in the case of supplying only the O₂ gas, the O₂ gas reaches the vicinity of the target and, thus, the pressure is not sufficiently decreased (the O₂ gas is not sufficiently discharged) unless the vacuum exhaustion is performed more than 600 sec. As for this, in the case of supplying Ar gas during the supply of O₂ gas, the exhaustion time was the same as that in the case of supplying only the Ar gas. It was confirmed from the above that it is possible to suppress O₂ gas from reaching the vicinity of the target by supplying Ar gas during the supply of O₂ gas.

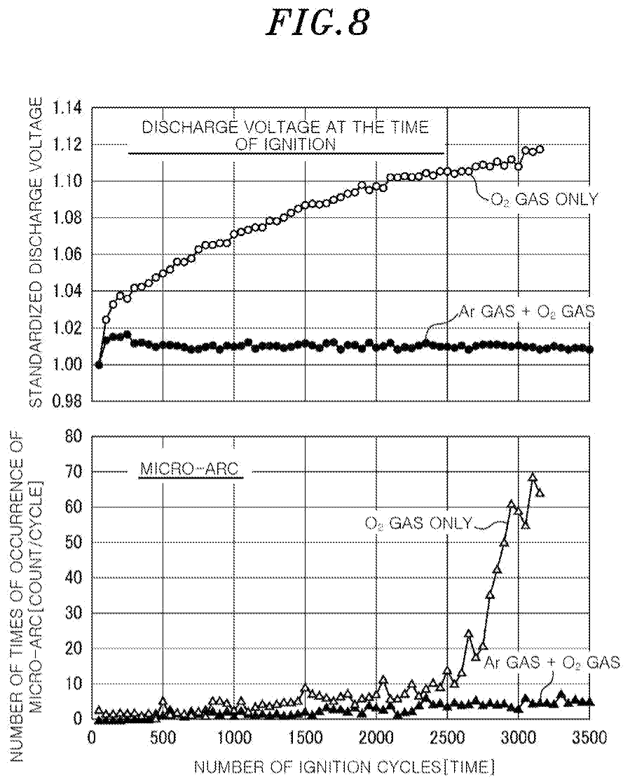

Next, the effect of supplying Ar gas together with O₂ gas during the oxidation treatment was checked. Here, Mg was used as a target, and the sputtering was performed by igniting plasma under the conditions: supply power of 700 W, Ar gas flow rate of 400 sccm, and processing time of 4 sec. Thereafter, the oxidation treatment was performed. The oxidation treatment was performed under common conditions: O₂ gas flow rate of 2000 sccm and processing time of 30 sec, and under two types of conditions: a case where Ar gas was not supplied during the oxidation treatment and a case where Ar gas was supplied at 1000 sccm. The pressure during the treatment was 2×10⁻² Torr, and the temperature was room temperature. The treatment was repeated under the above conditions, and a discharge voltage at the time of ignition and the number of times of occurrence of micro-arc were monitored. The result is shown in FIG. 8.

As shown in FIG. 8, in the case of supplying only O₂ gas, the discharge voltage at the time of ignition tends to increase as an ignition cycle increases, and the number of occurrence of micro-arc increases abruptly when the number of ignition cycles exceeds a certain number of times. On the other hand, in the case of supplying both of O₂ gas and Ar gas, the target surface oxidation is suppressed. As a result, it was confirmed that the discharge voltage during the sputtering was stable and there was no abrupt increase in the micro-arc.

### Second Embodiment

Next, the second embodiment will be described.

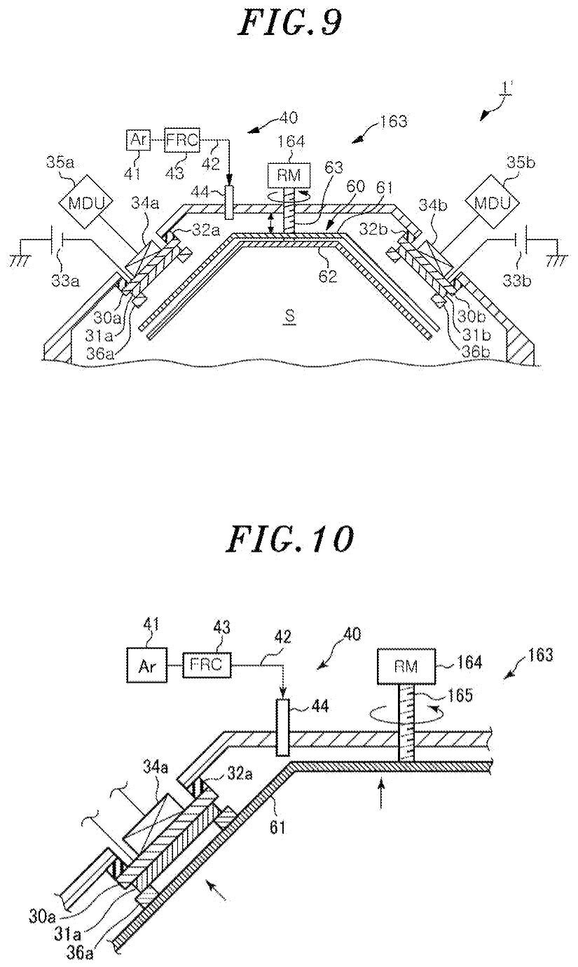

FIG. 9 is a cross-sectional view showing a portion of the film forming apparatus according to the second embodiment. The configuration of the film forming apparatus 1′ according to the second embodiment is basically the same as that of the film forming apparatus according to the first embodiment except that the rotation mechanism 63 of FIG. 1 is replaced by a rotation/elevating mechanism 163. Since other configurations are the same as those of the first embodiment, the description thereof will be omitted.

The rotation/elevating mechanism 163 switches the partition unit 60 between the open state and the closed state, and vertically moves up and down the partition unit 60 close to or separated from the targets 31a and 31b. More specifically, the rotation/elevating mechanism 163 includes a rotation mechanism (RM) 164 having the same structure as that of the rotation mechanism 63 of FIG. 1, and a rotary shaft 165 formed of a screw rod extending from the rotation mechanism 164 and supporting the first partition plate 61. Further, in addition to the rotary shaft 165, a rotary shaft (not shown) that supports the second partition plate 62 is provided. The rotation/elevating mechanism 163 rotates the rotary shaft 165 formed of a screw rod using the rotating mechanism 164, so that the first partition plate 61 is rotated to the open state or the closed state and vertically moved at the same time. The second partition plate 62 may be vertically moved together with the first partition plate 61.

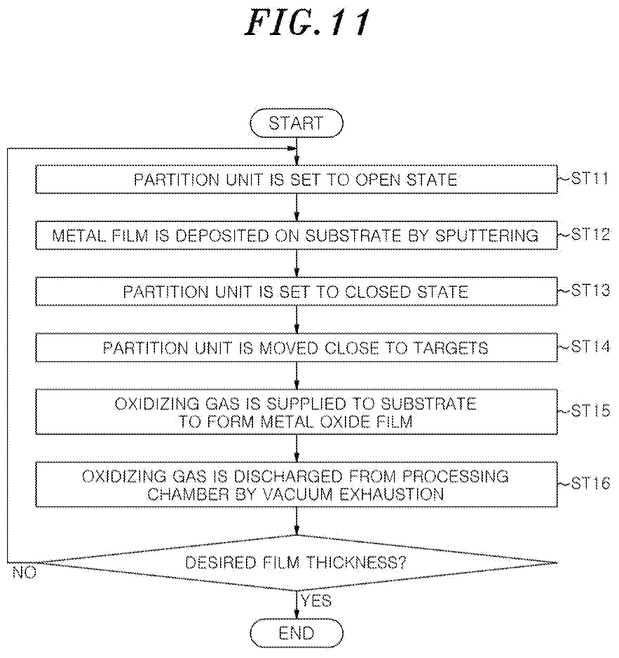

The rotation/elevating mechanism 163 can move the partition unit 60 close to the targets 31a and 31b. In other words, by raising the first partition plate 61 of the partition unit 60, the first partition plate 61 can be moved close to the targets 31a and 31b. By moving the partition unit 60 (the first partition plate 61) close to the targets 31a and 31b, the path through which the oxidizing gas reaches the targets 31a and 31b may be narrowed, and the oxidizing gas can be suppressed from reaching the targets 31a and 31b. Particularly, as shown in FIG. 10, when the first partition plate 61 is brought into close contact with the ring-shaped members 36a and 36b, the space surrounded by the targets 31a and 31b, the partition plate 61, and the ring-shaped members 36a and 36b is substantially closed. Accordingly, it is possible to more effectively suppress the oxidizing gas from reaching the surfaces of the targets 31a and 31b. Further, by using the rotation/elevating mechanism 163, the switching from the open state to the closed state and the operation of moving the partition unit 60 (partition plate 61) close to the targets 31a and 31b can be performed at them same time.

Next, a film forming method according to one embodiment that can be performed by the film forming apparatus according to the second embodiment configured as described above will be described with reference to the flowchart of FIG. 11.

The film forming method of FIG. 11 includes steps ST11, ST12, ST13, ST14, ST15, and ST16.

First, prior to the execution of the film forming method, the gate valve 14 is opened, and the substrate W is loaded into the processing chamber 10 from the transfer chamber (not shown) adjacent to the processing chamber 10 by a transfer unit (not shown) and held by the substrate holder 20.

In step ST11, the partition unit 60 is set to the open state. Specifically, the first and second partition plates 61 and 62 are set to the open state in which the openings 61a and 62a are located at positions corresponding to the targets 31a and 31b, respectively. In this state, the centers of the openings 61a and 62a coincide with the centers of the targets 31a and 31b. At this time, the head portion 51 of the oxidizing gas introduction mechanism 50 is located at the retreat position.

In step ST12, a metal film such as an Mg film or an Al film is deposited on the substrate W on the substrate holder 20 by sputtering. This step is performed in the same manner as that in step ST1 of the first embodiment.

In step ST13, the partition unit 60 is set to the closed state. Specifically, first, the second partition plate 62 is rotated to the closed state and, then, the first partition plate 61 is rotated to the closed state.

In step ST14, the partition unit 60 is raised to move close to the targets 31a and 31b. Specifically, by raising the first partition plate 61, the first partition plate 61 is moved close to the targets 31a and 31b. Preferably, as shown in FIG. 10, the partition unit 60 (the first partition plate 61) is brought into close contact with the ring-shaped members 36a and 36b. At this time, the first partition plate 61 can be rotated and raised at the same time.

In step ST15, an oxidizing gas, e.g., O₂ gas, is supplied to the substrate W, and the metal film deposited on the substrate W is oxidized to form a metal oxide film. At this time, the head portion 51 of the oxidizing gas introduction mechanism 50 is moved to the oxidation treatment position directly above the substrate holder 20, and the oxidizing gas is supplied from the head portion 51 of the oxidizing gas introduction mechanism 50 to the substrate W. The oxidation treatment of step ST15 is performed in the same manner as that in step ST3 of the first embodiment.

In step ST16, the oxidizing gas supplied in step ST3 is discharged from the processing chamber 10 by vacuum exhaustion.

By repeating steps ST11 to ST16 a predetermined number of times, a metal oxide film having a desired film thickness is formed.

In accordance with the present embodiment, the deposition of the metal film and the oxidation treatment of the metal film can be performed in one processing chamber, so that the formation of the metal oxide film can be performed quickly as in the technique of Patent Document 1. Further, since the partition unit 60 (first partition plate 61) is moved close to the targets 31a and 31b, the intrusion path of the oxidizing gas is narrowed, which makes it possible to suppress the oxidizing gas from reaching the targets 31a and 31b during the oxidation treatment. Particularly, when the first partition plate 61 is brought into close contact with the ring-shaped members 36a and 36b, the space surrounded by the targets 31a and 31b, the partition plate 61 and the ring-shaped members 36a and 36b becomes substantially closed. Accordingly, it is possible to more effectively suppress the oxidizing gas from reaching the surfaces of the targets 31a and 31b.

Therefore, it is possible to suppress the oxidation of the surfaces of the targets 31a and 31b, and also possible to suppress the decrease in the sputtering rate, the change in the discharge voltage, and the occurrence of arc discharge at the time of depositing the metal film by sputtering. In addition, the change in the thickness of the metal film is also suppressed. Accordingly, it is possible to stably manufacture an element having the same characteristics.

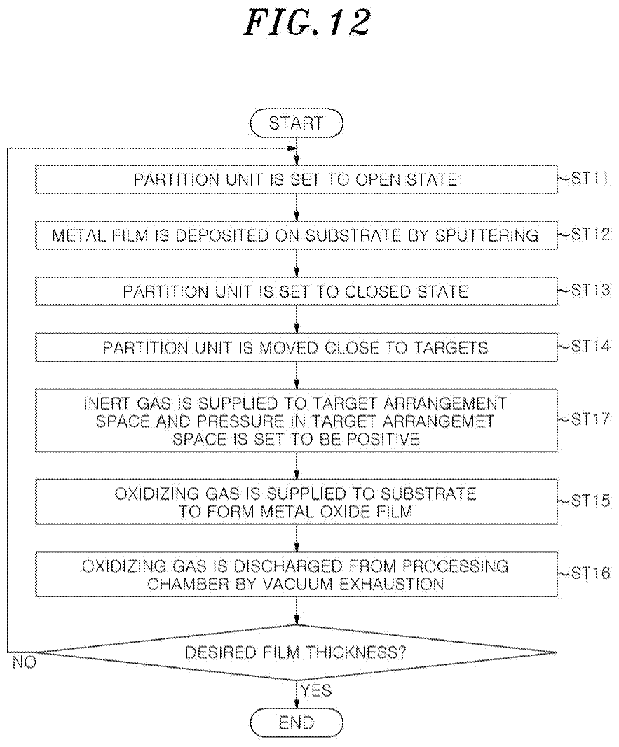

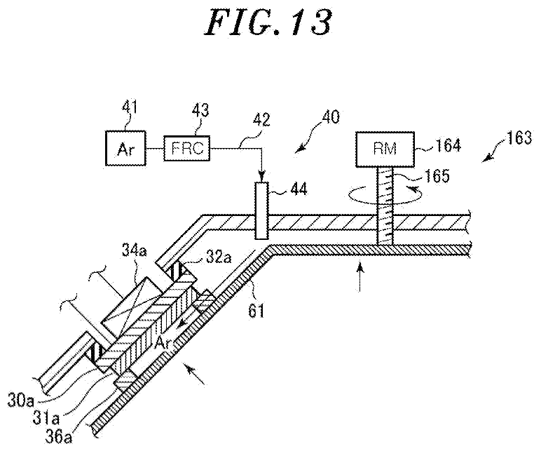

In the second embodiment, as shown in FIG. 12, step ST17 may be performed after step ST14 and before the oxidation treatment of step ST15. In step ST17, as shown in FIG. 13, an inert gas such as Ar, He, Ne, Kr, He or the like is supplied from the gas supply unit 40 to the target arrangement space, and the pressure in the target arrangement space is set to be positive compared to the pressure in the processing space S near the substrate W. Accordingly, it is possible to further suppress the oxidizing gas from reaching the targets 31a and 31b. The oxidation of the surfaces of the targets 31a and 31b can be suppressed more effectively. In this case, in the exhaust process of step ST16, the inert gas as well as the oxidizing gas are discharged from the processing chamber 10.

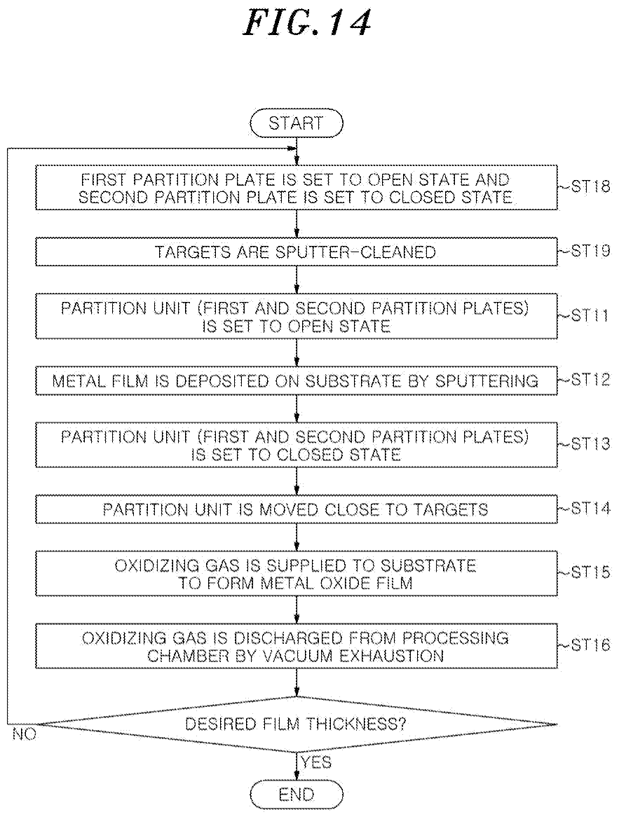

Further, in the second embodiment, as shown in FIG. 14, steps ST18 and ST19 may be performed prior to step ST11. In step ST18, the first partition plate 61 is set to the open state and the second partition plate 62 is set to the closed state. In step ST19, a voltage is applied to the targets 31a and 31b, and the targets 31a and 31b are sputter-cleaned. Accordingly, the natural oxide films on the surfaces of the targets 31a and 31b are removed. At this time, the sputter particles are deposited on the second partition plate 62 without reaching the substrate W. After step ST19, the partition plate 62 is set to the open state, i.e., the state of step S11 is obtained. By removing the natural oxide films of the targets 31a and 31b by sputtering, the influence of the natural oxide films of the targets 31a and 31b can be further reduced.

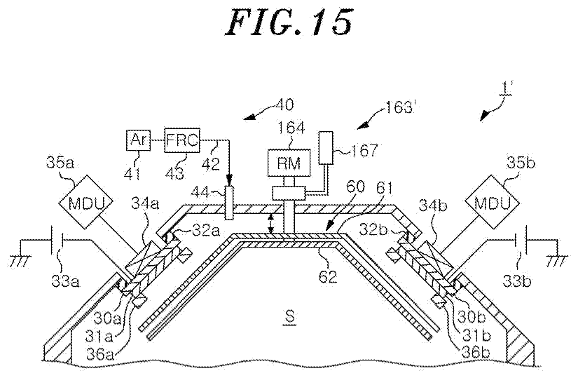

As a mechanism for moving the partition unit 60 close to the targets 31a and 31b, the mechanism shown in FIG. 15 can also be used. In FIG. 15, the rotary shaft 166 of the rotating mechanism 164 does not have a screw, and an elevating mechanism (EM) 167 is separately provided to vertically move up and down the partition unit 60 (the first partition plate 61). By raising the partition unit 60 (the first partition plate 61) using the elevating mechanism 167, the partition unit 60 (partition plate 61) can be moved close to the targets 31a and 31b.

### Other Applications

The embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

For example, the sputtering method for forming a metal film described in the above embodiments is an example. Another sputtering method may be used, or sputter particles may be emitted by a method other than that of the present disclosure. Further, although the oxidizing gas is supplied to the substrate from the head portion disposed above the substrate in the above embodiments, the present disclosure is not limited thereto.

### DESCRIPTION OF REFERENCE NUMERALS

1: film forming apparatus
10: processing chamber
10a: chamber main body
10b: lid
20: substrate holder
30a, 30b: target electrode
31a, 31b: target
33a, 33b: power source
40: gas supply (oxidizing gas arrival suppression mechanism)
50: oxidizing gas introduction mechanism
51: head portion
57: oxidizing gas supply unit
60: partition unit
61: first partition plate
163: rotation/elevating mechanism (oxidizing gas arrival suppression mechanism)
167: elevating mechanism (oxidizing gas arrival suppression mechanism)
W: Substrate

1. A film forming apparatus for forming a metal oxide film on a substrate, comprising:
a processing chamber;
a substrate holder configured to hold a substrate in the processing chamber;
a target electrode disposed above the substrate holder and configured to hold a target made of a metal and supply an electrical power from a power source to the target;
an oxidizing gas introduction mechanism configured to supply an oxidizing gas to the substrate held by the substrate holder; and
a gas supply unit configured to supply an inert gas to a target arrangement space where the target is disposed,
wherein a constituent metal is discharged in the form of sputter particles from the target supplied with the electrical power through the target electrode, and deposited on the substrate as a metal film, and the metal film is oxidized by the oxidizing gas introduced by the oxidizing gas introduction mechanism, thereby forming a metal oxide film, and
when the oxidizing gas is introduced, the gas supply unit supplies the inert gas to the target arrangement space so that a pressure in the target arrangement space is positive with respect to a pressure in a processing space where the substrate is disposed.

2. The film forming apparatus of claim 1, further comprising:
a partition unit that is disposed between the target arrangement space and the processing space, and becomes in a closed state in which the target arrangement space and the processing space are separated when the oxidizing gas is introduced and becomes in an open state when the metal film is deposited; and
an opening/closing mechanism configured to put the partition unit to the open state or the closed state.

3. The film forming apparatus of claim 1, wherein the oxidizing gas introduction mechanism has a head portion that is movable between an oxidation treatment position in the processing space and a retreat position distant from the processing space, and supply the oxidizing gas to the substrate when the head portion is located at the oxidation treatment position.

4. A film forming apparatus for forming a metal oxide film on a substrate, comprising:
a processing chamber;
a substrate holder configured to hold a substrate in the processing chamber;
a target electrode disposed above the substrate holder and configured to hold a target made of a metal and supply an electrical power from a power source to the target;
an oxidizing gas introduction mechanism configured to supply an oxidizing gas to the substrate;
a partition unit that is disposed between a target arrangement space where the target is disposed and a processing space where the substrate is disposed, and becomes in a closed state in which the target arrangement space and the processing space are separated when the oxidizing gas is introduced and becomes in an open state when a metal film is deposited;
an opening/closing mechanism configured to put the partition unit in the open state or the closed state; and
a moving mechanism configured to move the partition unit with respect to the target,
wherein a constituent metal is discharged in the form of sputter particles from the target supplied with the electrical power through the target electrode, and deposited on the substrate as a metal film, and the metal film is oxidized by the oxidizing gas introduced by the oxidizing gas introduction mechanism, thereby forming a metal oxide film, and
the moving mechanism moves the partition unit close to the target when the oxidizing gas is introduced.

5. The film forming apparatus of claim 4, wherein a ring-shaped member is disposed at an outer peripheral portion of a surface of the target, and
the moving mechanism brings the partition unit into close contact with the ring-shaped member when the oxidizing gas is introduced.

6. The film forming apparatus of claim 4, wherein the partition unit has an opening corresponding to the target,
the opening/closing mechanism rotates the partition unit to the open state in which the opening is located at a position corresponding to the target or to the closed state in which the opening is located at a position that does not correspond to the target, and
the moving mechanism vertically moves up or down the partition unit close to or separated from the target.

7. The film forming apparatus of claim 6, further comprising:
a rotation/elevating mechanism in which the opening/closing mechanism and the moving mechanism are integrated,
wherein the rotation/elevating mechanism includes a rotary shaft formed of a screw rod attached to the partition unit and a rotation mechanism configured to rotate the rotary shaft, and
the partition unit is rotated and vertically moved up and down by rotating the rotary shaft using the rotating mechanism.

8. The film forming apparatus of claim 6, wherein the partition unit includes a first partition plate on the target side and a second partition plate on the processing space side, the first and second partition plates are arranged to overlap in a vertical direction with each other and independently rotatable, and have openings corresponding to the target,
the opening/closing mechanism rotates the first partition plate and the second partition plate to thereby move to the open state in which the opening is located at a position corresponding to the target or to the closed state in which the opening is located at a position that does not correspond to the target,
when both of the first partition plate and the second partition plate are in the open state, the metal film is deposited on the substrate,
when both the first partition plate and the second partition plate are in the closed state, the metal film is oxidized, and
when the first partition plate is in the open state and the second partition plate is in the closed state, the surface of the target is sputter-cleaned by supplying an electrical power to the target through the target electrode.

9. The film forming apparatus of claim 4, further comprising:
a gas supply unit configured to supply an inert gas to the target arrangement space where the target is disposed,
wherein when the oxidizing gas is introduced, the gas supply unit supplies the inert gas to the target arrangement space so that a pressure in the target arrangement space is positive with respect to a pressure in the processing space in which the substrate is disposed.

10. The film forming apparatus of claim 4, wherein the oxidizing gas introduction mechanism includes a head portion that is movable between an oxidation treatment position in the processing space and a retreat position distant from the processing space, and the oxidizing gas is supplied to the substrate when the head portion is located at the oxidation treatment position.

11. A film forming method for forming a metal oxide film on a substrate using a film forming apparatus,
wherein the film forming apparatus includes:
a processing chamber;
a substrate holder configured to hold a substrate in the processing chamber;
a target electrode disposed above the substrate holder and configured to hold a target made of a metal and supply an electrical power from a power source to the target;
an oxidizing gas introduction mechanism configured to supply an oxidizing gas to the substrate held by the substrate holder; and
a gas supply unit configured to supply an inert gas to a target arrangement space where the target is disposed,
the method comprising:
depositing a metal film on the substrate by supplying the electrical power to the target held by the target electrode to discharge a constituent metal from the target in the form of sputter particles;
supplying an inert gas from the gas supply unit to the target arrangement space so that a pressure in the target arrangement space is positive with respect to a pressure in a processing space where the substrate is disposed;
oxidizing the metal film by supplying the oxidizing gas from the oxidizing gas introduction mechanism to the substrate while maintaining the positive pressure in the target arrangement space; and
discharging the inert gas and the oxidizing gas from the processing chamber; and
repeating said depositing the metal film, said supplying the inert gas, said oxidizing the metal film, and said discharging the inert gas and the oxidizing gas once or multiple times.

12. The film forming method of claim 11, wherein the film forming apparatus further includes:
a partition unit that is disposed between the target arrangement space and the processing space, and becomes be in a closed state in which the target arrangement space and the processing space are separated when the oxidizing gas is introduced and becomes in an open state when the metal film is deposited,
wherein the partition unit is in the open state when the metal film is deposited and is in the closed state when the metal film is oxidized.

13. A film forming method for forming a metal oxide film on a substrate using a film forming apparatus,
wherein the film forming apparatus includes:
a processing chamber;
a substrate holder configured to hold a substrate in the processing chamber;
a target electrode disposed above the substrate holder and configured to hold a metal target and supply an electrical power from a power source to the target;
an oxidizing gas introduction mechanism configured to supply an oxidizing gas to the substrate; and
a partition unit that is disposed between the target arrangement space and the processing space, and becomes in a closed state in which the target arrangement space and the processing space are partitioned when the oxidizing gas is introduced and becomes in an open state when a metal film is deposited,
the method comprising:
setting the partition unit to an open state;
depositing the metal film on the substrate by supplying the electrical power to the target held by the target electrode to discharge a constituent metal from the target in the form of sputter particles;
setting the partition unit to a closed state;
moving the partition close to the target;
oxidizing the metal film by supplying the oxidizing gas to the substrate from the oxidizing gas introduction mechanism; and
discharging the oxidizing gas from the processing chamber,
wherein said setting the partition unit to the open state, said depositing the metal film, said setting the partition unit to the closed state, said moving the partition unit close to the target, said oxidizing the metal film, and said discharging the oxidizing gas are repeated once or multiple times.

14. The film forming method of claim 13, wherein in the film forming apparatus, a ring-shaped member is disposed at an outer peripheral portion of a surface of the target, and
in said moving the partition unit close to the target, the partition unit is brought into close contact with the ring-shaped member.

15. The film forming method of claim 13, wherein the partition unit has an opening corresponding to the target, and
the partition plate is rotated to the open state in which the opening is located at a position corresponding to the target or to the closed state in which the opening is located at a position that does not correspond to the target, and is moved up close to the target.

16. The film forming method of claim 15, wherein the partition unit includes a first partition plate on the target side and a second partition plate on the processing space side, the first and second partition plates are arranged to overlap in a vertical direction with each other and independently rotatable, and have openings corresponding to the target,
the first partition plate and the second partition plate are rotated to the open state in which the opening is located at a position corresponding to the target or to the closed state in which the opening is located at a position that does not correspond to the target,
when both of the first partition plate and the second partition plate are in the open state, the metal film is deposited on the substrate, and
when both the first partition plate and the second partition plate are in the closed state, the metal film is oxidized,
the method further comprising, before said setting the partition unit to the open state:
setting the first partition plate to the open state and setting the second partition plate to the closed state; and
supplying an electrical power to the target through the target electrode and sputter-cleaning the surface of the target.

17. The film forming apparatus of claim 13, further comprising:
a gas supply unit configured to supply an inert gas to the target arrangement space where the target is disposed,
the method further comprising, between said moving the partition unit close to the target and said oxidizing the metal film:
supplying the inert gas from the gas supply unit to the target arrangement space so that a pressure therein is positive with respect to a pressure in the processing space where the substrate is disposed.
